(19) United States
(12) Patent Application Publication
(10) Pub. No.: US 2012/0255601 A1
(43) Pub. Date: Oct. 11, 2012

(54) Hybrid Solar Cell and Method for Manufacturing the Same

(76) Inventor: Jin Hyuk Yoo, Seongnam-si (KR)

(21) Appl. No.: 13/502,728

(22) PCT Filed: Jan. 1, 2010
(86) PCT No.: PCT/KR2010/000001

§ 371 Date: Apr. 18, 2012

(30) Foreign Application Priority Data
Dec. 30, 2009 (KR) 10-2009-0134531

(51) Int. Cl. H01L 31/065; H01L 31/18; H01L 31/0224

(52) U.S. Cl. 136/255; 136/256; 438/98; 438/87; 257/E31.126; 257/E31.055

(57) ABSTRACT

A hybrid solar cell and a method for manufacturing the same is disclosed, wherein the hybrid solar cell comprises a semiconductor wafer having a predetermined polarity; a first semiconductor layer on one surface of the semiconductor wafer; a second semiconductor layer on the other surface of the semiconductor wafer, wherein the second semiconductor layer is different in polarity from the first semiconductor layer; a first electrode on the first semiconductor layer; a second electrode on the second semiconductor layer; and at least one of first and second interfacial layers, wherein the first interfacial layer containing ZnO is formed between the first semiconductor layer and the first electrode, and the second interfacial layer containing ZnO is formed between the second semiconductor layer and the second electrode, wherein the hybrid solar cell is provided with the interfacial layer between the first semiconductor layer and the first electrode and/or between the second semiconductor layer and the second electrode, so that it is possible to prevent the material of the electrode from permeating into the semiconductor layer, and to collect the carriers in the semiconductor wafer and to smoothly drift the collected carriers to the electrode, thereby improving the cell efficiency.

### CROSS REFERENCE TO RELATED APPLICATIONS

This application claims the benefit of the Korean Patent Application No. P2009-0134531 filed on Dec. 30, 2009, which is hereby incorporated by reference as if fully set forth herein.

### BACKGROUND OF THE INVENTION

1. Field of the Invention

The present invention relates to a solar cell, and more particularly, to a hybrid solar cell.

2. Discussion of the Related Art

A solar cell with a property of semiconductor converts a light energy into an electric energy.

The solar cell is formed in a PN junction structure where a positive(P)-type semiconductor makes a junction with a negative(N)-type semiconductor. When solar ray is incident on the solar cell with the PN junction structure, holes (+) and electrons (−) are generated in the semiconductor owing to the energy of the solar ray. By an electric field generated in the PN junction, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. The thin film type solar cell is advantageous in that its manufacturing cost is relatively lower than that of the wafer type solar cell.

There has been proposed a hybrid solar cell obtained by combining the wafer type solar cell and the thin film type solar cell, which will be explained as follows with reference to the accompanying drawings.

FIG. 1 is a cross section view illustrating a related art hybrid solar cell.

As shown in FIG. 1, the related art hybrid solar cell includes a semiconductor wafer 10, a first semiconductor layer 20, a first electrode 30, a second semiconductor layer 40, and a second electrode 50.

The first semiconductor layer 20 is formed in a thin-film type on an upper surface of the semiconductor wafer 10; and the second semiconductor layer 40 is formed in a thin-film type on a lower surface of the semiconductor wafer 10. Thus, a PN junction structure can be made by combining the semiconductor wafer 10, the first semiconductor layer 20, and the second semiconductor layer 40.

The first electrode 30 is formed on the first semiconductor layer 20, and the second electrode 50 is formed on the second semiconductor layer 40, whereby the first and second electrodes 30 and 50 respectively serve as (+) and (−) polarities of the solar cell.

However, the related art hybrid solar cell has the following disadvantages.

During the process for forming the first or second electrode 30 or 50 in the related art hybrid solar cell, a metal material of the first or second electrode 30 or 50 may permeate into the first or second semiconductor layer 20 or 40, thereby lowering the cell efficiency.

Also, carriers generated in the PN junction structure of the related art hybrid solar cell do not smoothly drift to the first or second electrode 30 or 50, thereby lowering the short-circuit current density and cell efficiency.

### SUMMARY OF THE INVENTION

Accordingly, the present invention is directed to a hybrid solar cell that substantially obviates one or more problems due to limitations and disadvantages of the related art.

An object of the present invention is to provide a hybrid solar cell which is capable of preventing a metal material of an electrode from permeating into a semiconductor layer when forming the electrode, and which is capable of smoothly drifting carriers generated in a PN junction structure to the electrode, to thereby improve short-circuit current density and cell efficiency.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a hybrid solar cell comprising a semiconductor wafer having a predetermined polarity; a first semiconductor layer on one surface of the semiconductor wafer; a second semiconductor layer on the other surface of the semiconductor wafer, wherein the second semiconductor layer is different in polarity from the first semiconductor layer; a first electrode on the first semiconductor layer; a second electrode on the second semiconductor layer; and at least one of first and second interfacial layers, wherein the first interfacial layer containing ZnO is formed between the first semiconductor layer and the first electrode, and the second interfacial layer containing ZnO is formed between the second semiconductor layer and the second electrode.

In another aspect of the present invention, a method for manufacturing a hybrid solar cell comprises forming a first semiconductor layer on one surface of a semiconductor wafer having a predetermined polarity; forming a first interfacial layer containing ZnO on the first semiconductor layer by CVD; forming a first electrode on the first interfacial layer; forming a second semiconductor layer on the other surface of the semiconductor wafer, wherein the second semiconductor layer is different in polarity from the first semiconductor layer; forming a second interfacial layer containing ZnO on the second semiconductor layer by CVD; and forming a second electrode on the second interfacial layer.

In another aspect of the present invention, a method for manufacturing a hybrid solar cell comprises forming a first semiconductor layer on one surface of a semiconductor wafer having a predetermined polarity; forming a first transparent conductive layer on the first semiconductor layer; forming a first electrode on the first transparent conductive layer; forming a second semiconductor layer on the other surface of the semiconductor wafer, wherein the second semiconductor layer is different in polarity from the first semiconductor layer; forming a second interfacial layer containing ZnO on the second semiconductor layer by CVD; and forming a second electrode on the second interfacial layer.

In another aspect of the present invention, a method for manufacturing a hybrid solar cell comprises forming a first semiconductor layer on one surface of a semiconductor wafer having a predetermined polarity; forming a first interfacial layer containing ZnO on the first semiconductor layer by CVD; forming a first electrode on the first interfacial layer; forming a second semiconductor layer on the other surface of the semiconductor wafer, wherein the second semiconductor layer is different in polarity from the first semiconductor layer; forming a second transparent conductive layer on the second semiconductor layer; and forming a second electrode on the second transparent conductive layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a related art hybrid solar cell;

FIG. 2 is a cross section view illustrating a hybrid solar cell according to the first embodiment of the present invention;

FIG. 3 is a cross section view illustrating a hybrid solar cell according to the second embodiment of the present invention;

FIG. 4 is a cross section view illustrating a hybrid solar cell according to the third embodiment of the present invention;

FIG. 5 is a cross section view illustrating a hybrid solar cell according to the fourth embodiment of the present invention;

FIG. 6 is a cross section view illustrating a hybrid solar cell according to the fifth embodiment of the present invention;

FIG. 7 is a cross section view illustrating a hybrid solar cell according to the sixth embodiment of the present invention;

FIG. 8 is a cross section view illustrating a hybrid solar cell according to the seventh embodiment of the present invention;

FIG. 9 is a cross section view illustrating a hybrid solar cell according to the eighth embodiment of the present invention;

FIG. 10 is a cross section view illustrating a hybrid solar cell according to the ninth embodiment of the present invention;

FIG. 11(A to F) is a series of cross section views illustrating a method for manufacturing a hybrid solar cell according to one embodiment of the present invention;

FIG. 12(A to F) is a series of cross section views illustrating a method for manufacturing a hybrid solar cell according to another embodiment of the present invention; and

FIG. 13(A to F) is a series of cross section views illustrating a method for manufacturing a hybrid solar cell according to another embodiment of the present invention.

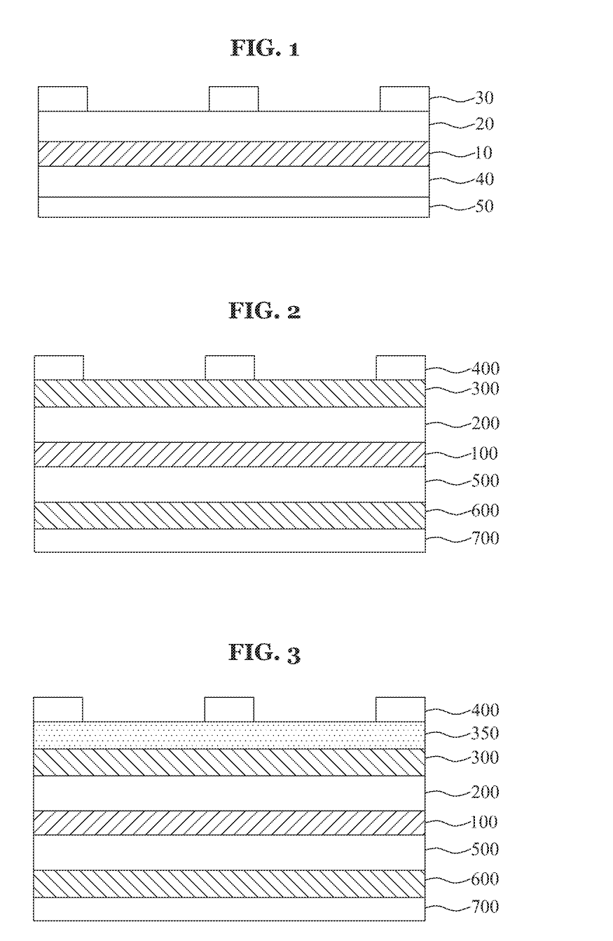

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a hybrid solar cell according to the present invention and a method for manufacturing the same will be described with reference to the accompanying drawings.

### Structure of Hybrid Solar Cell

### First Embodiment

FIG. 2 is a cross section view illustrating a hybrid solar cell according to the first embodiment of the present invention.

As shown in FIG. 2, the hybrid solar cell according to the first embodiment of the present invention includes a semiconductor wafer 100, a first semiconductor layer 200, a first interfacial layer 300, a first electrode 400, a second semiconductor layer 500, a second interfacial layer 600, and a second electrode 700.

The semiconductor wafer 100 may be formed of a silicon wafer, and more particularly, an N-type silicon wafer. The semiconductor wafer 100 may be formed of a P-type silicon wafer.

The semiconductor wafer 100 may be identical in polarity to any one of the first and second semiconductor layers 200 and 500.

The first semiconductor layer 200 is formed in a thin-film type on an upper surface of the semiconductor wafer 100. The first semiconductor layer 200 can make a PN junction with the semiconductor wafer 100. Thus, if the semiconductor wafer 100 is formed of the N-type silicon wafer, the first semiconductor layer 200 may be formed of a P-type semiconductor layer. Especially, the first semiconductor layer 200 may be formed of P-type amorphous silicon doped with a group III element in the periodic table, for example, boron (B).

The first interfacial layer 300 is formed between the first semiconductor layer 200 and the first electrode 400. The first interfacial layer 300 functions as a barrier to prevent a material of the first electrode 400 from permeating into the first semiconductor layer 200. Also, the first interfacial layer 300 collects carriers generated in the semiconductor wafer 100, and makes the collected carriers drift to the first electrode 400. The first interfacial layer 300 is formed of a transparent conductive material containing ZnO, for example, ZnO:B or ZnO:Al.

A typical example of the transparent conductive material may be ITO (Indium Tin Oxide). In case of the present invention, the first interfacial layer 300 is formed of the transparent conductive material containing ZnO instead of ITO. The reason why the first interfacial layer 300 is formed of the transparent conductive material containing ZnO instead of ITO will be explained as follows.

The ITO is formed by a physical vapor deposition method such as a sputtering method. If the first interfacial layer 300 is formed by the physical vapor deposition method, the first interfacial layer 300 might be not uniform, and also have a defect such as a void therein. If the defect such as the void occurs in the first interfacial layer 300, the first interfacial layer 300 cannot sufficiently serve as the barrier, and a contact area between the first interfacial layer 300 and the first electrode 400 is decreased so that it is difficult to realize the smooth collection and drift of the carriers, thereby lowering a short-circuit current density. Especially, if the semiconductor wafer 100 has an uneven surface made by a texturing process, the first semiconductor layer 200 formed on the semiconductor wafer 100 also has an uneven surface. In case of that the first interfacial layer 300 is formed on the first semiconductor layer 200 with the uneven surface, when an ITO layer is formed by the physical vapor deposition method such as the sputtering method, the defect such as the void may be increased in the ITO layer.

In order to overcome this problem, instead of using ITO, the first interfacial layer 300 is formed of the material suitable for a chemical vapor deposition method such as MOCVD (Metal Organic Chemical Vapor Deposition). Especially, the first interfacial layer 300 is formed of the transparent conductive material containing ZnO, for example, ZnO:B or ZnO:Al corresponding to the optimal material which is capable of performing the barrier function and enabling the smooth collection and drift of the carriers. The layer formed by the chemical vapor deposition method such as MOCVD becomes more uniform than the layer formed by the physical vapor deposition method such as the sputtering method. Especially, when the first interfacial layer 300, which is formed of the transparent conductive material containing ZnO to enable the chemical vapor deposition method such as MOCVD, is formed on the first semiconductor layer 200 with the uneven surface, it is capable of preventing the defect such as the void from occurring in the first interfacial layer 300.

Preferably, the first interfacial layer 300 has 110 nm to 600 nm thickness. If the thickness of the first interfacial layer 300 is less than 110 nm, the first interfacial layer 300 cannot sufficiently serve as the barrier, and also cannot make the smooth collection and drift of the carriers. Meanwhile, if the thickness of the first interfacial layer 300 is more than 600 nm, the short-circuit current density is lowered so that the cell efficiency is also lowered.

Each first electrode 400 is formed on the first interfacial layer 300. Preferably, the plurality of first electrodes 400 are formed at fixed intervals so that solar ray can be transmitted to the inside of the solar cell through the interval between each first electrode 400. This is because the first electrode 400 is positioned at the most frontal portion of the solar cell. If using an opaque metal material for each first electrode 400, the plurality of first electrodes 400 are formed at fixed intervals so that the solar ray can be transmitted to the inside of the solar cell through the interval between each first electrode 400.

The first electrode 400 may be formed of a metal material, for example, Ag, Al, Ag+Al, Ag+Mg, Ag+Mn, Ag+Sb, Ag+Zn, Ag+Mo, Ag+Ni, Ag+Cu, or Ag+Al+Zn.

The second semiconductor layer 500 is formed in a thin-film type on a lower surface of the semiconductor wafer 100. The second semiconductor layer 500 is different in polarity from the first semiconductor layer 200. If the first semiconductor layer 200 is formed of the P-type semiconductor layer doped with the group III element in the periodic table, for example, boron (B); the second semiconductor layer 500 may be formed of the N-type semiconductor layer doped with a group V element in the periodic table, for example, phosphorous (P). Especially, the second semiconductor layer 500 may be formed of N-type amorphous silicon.

The second interfacial layer 600 is formed between the second semiconductor layer 500 and the second electrode 700.

The second interfacial layer 600 functions as a barrier to prevent a material of the second electrode 700 from permeating into the second semiconductor layer 500. Also, the second interfacial layer 600 collects carrier generated in the semiconductor wafer 100; and makes the collected carriers drift to the second electrode 700.

According to the same aforementioned reason as the first interfacial layer 300, the second interfacial layer 600 is formed of the transparent conductive material containing ZnO, for example, ZnO:B or ZnO:Al. Preferably, the second interfacial layer 600 has 110 nm to 600 nm thickness.

The second electrode 700 is formed on the second interfacial layer 600. The second electrode 700 is positioned at the most rear portion of the solar cell. That is, even though each second electrode 700 is formed of the opaque metal material, there is no need to form the plurality of second electrodes 700 at fixed intervals. Thus, the second electrode 700 may be formed on an entire surface of the second interfacial layer 600.

The second electrode 700 may be formed of the same material as that of the first electrode 400, for example, Ag, Al, Ag+Al, Ag+Mg, Ag+Mn, Ag+Sb, Ag+Zn, Ag+Mo, Ag+Ni, Ag+Cu, or Ag+Al+Zn.

For describing the following embodiments of the present invention, the same reference numbers will be used throughout the drawings to refer to the same or like parts as those of the first embodiment, and a detailed explanation for the same parts will be omitted.

### Second Embodiment

FIG. 3 is a cross section view illustrating a hybrid solar cell according to the second embodiment of the present invention. Except an additionally-formed first transparent conductive layer 350, the hybrid solar cell according to the second embodiment of the present invention is identical in structure to the hybrid solar cell shown in FIG. 2 according to the first embodiment of the present invention.

As shown in FIG. 3, the hybrid solar cell according to the second embodiment of the present invention is provided with the first transparent conductive layer 350 formed between a first interfacial layer 300 and a first electrode 400.

Owing to the additionally-formed first transparent conductive layer 350, carriers collected in the first interfacial layer 300 smoothly drift to the first electrode 400, and a thickness of the first interfacial layer 300 is decreased so that energy conversion efficiency can be improved by a resistance reduction.

The first transparent conductive layer 350 may be formed of a transparent conductive material, for example, SnO₂, SnO₂:F, or ITO (Indium Tin Oxide).

When the first transparent conductive layer 350 is additionally formed between the first interfacial layer 300 and the first electrode 400, a thickness of the first interfacial layer 300 is about 5 nm to 50 nm, and a thickness of the first transparent conductive layer 350 is about 60 nm to 180 nm.

If the thickness of the first interfacial layer 300 is less than 5 nm, the first interfacial layer 300 cannot sufficiently serve as the barrier, and also cannot make the smooth collection and drift of the carriers. Meanwhile, if the thickness of the first interfacial layer 300 is more than 50 nm, it is difficult to maximize resistance-reduction efficiency.

If the thickness of the first transparent conductive layer 350 is less than 60 nm, the carrier collection and drift efficiency may be lowered, and the range of reducing the thickness of the first interfacial layer 300 may be decreased. Meanwhile, if the thickness of the first transparent conductive layer 350 is more than 180 nm, the resistance may be increased.

### Third Embodiment

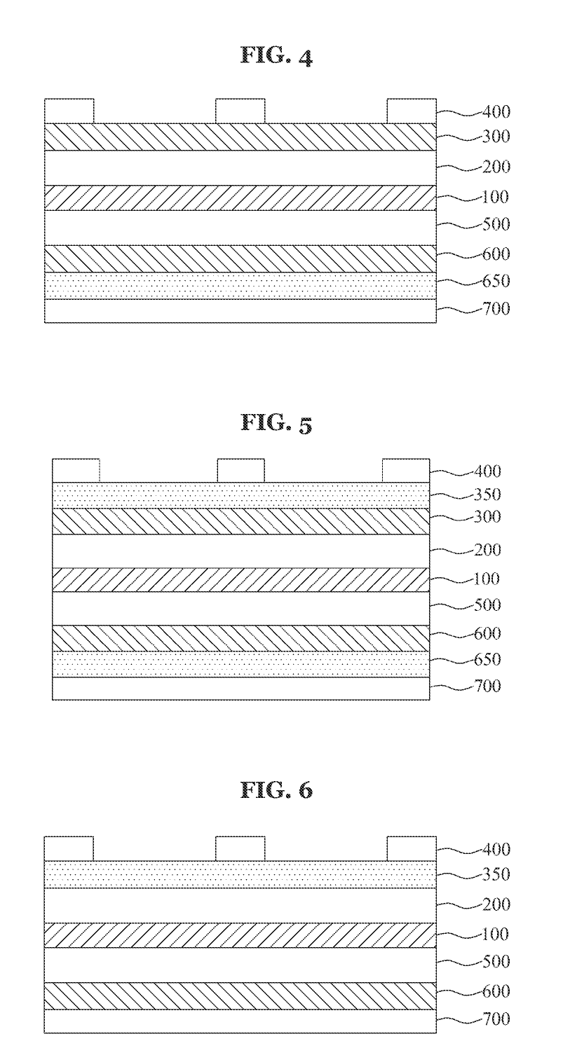

FIG. 4 is a cross section view illustrating a hybrid solar cell according to the third embodiment of the present invention. Except an additionally-formed second transparent conductive layer 650, the hybrid solar cell according to the third embodiment of the present invention is identical in structure to the hybrid solar cell shown in FIG. 2 according to the first embodiment of the present invention.

As shown in FIG. 4, the hybrid solar cell according to the third embodiment of the present invention is provided with the second transparent conductive layer 650 between a second interfacial layer 600 and a second electrode 700.

Owing to the additionally-formed second transparent conductive layer 650, carriers collected in the second interfacial layer 600 smoothly drift to the second electrode 700, and a thickness of the second interfacial layer 600 is decreased so that energy conversion efficiency can be improved by a resistance reduction.

The second transparent conductive layer 650 may be formed of a transparent conductive material, for example, SnO₂, SnO₂:F, or ITO (Indium Tin Oxide).

When the second transparent conductive layer 650 is additionally formed between the second interfacial layer 600 and the second electrode 600, a thickness of the second interfacial layer 600 is about 5 nm to 50 nm, and a thickness of the second transparent conductive layer 650 is about 60 nm to 180 nm.

If the thickness of the second interfacial layer 600 is less than 5 nm, the second interfacial layer 600 cannot sufficiently serve as the barrier, and also cannot make the smooth collection and drift of the carriers. Meanwhile, if the thickness of the second interfacial layer 600 is more than 50 nm, it is difficult to maximize resistance-reduction efficiency.

If the thickness of the second transparent conductive layer 650 is less than 60 nm, the carrier collection and drift efficiency may be lowered, and the range of reducing the thickness of the second interfacial layer 600 may be decreased. Meanwhile, if the thickness of the second transparent conductive layer 650 is more than 180 nm, the resistance may be increased.

### Fourth Embodiment

FIG. 5 is a cross section view illustrating a hybrid solar cell according to the fourth embodiment of the present invention. Except additionally-formed first and second transparent conductive layers 350 and 650, the hybrid solar cell according to the fourth embodiment of the present invention is identical in structure to the hybrid solar cell shown in FIG. 2 according to the first embodiment of the present invention.

As shown in FIG. 5, the hybrid solar cell according to the fourth embodiment of the present invention is provided with the first and second transparent conductive layers 350 and 650, wherein the first transparent conductive layer 350 is additionally formed between a first interfacial layer 300 and a first electrode 400, and the second transparent conductive layer 650 is additionally formed between a second interfacial layer 600 and a second electrode 700.

The first and second transparent conductive layers 350 and 650 provided in the hybrid solar cell according to the fourth embodiment of the present invention are identical in function and material to those of the second and third embodiments of the present invention. Furthermore, first and second transparent conductive layers to be described in the following embodiments of the present invention are identical in function and material to those of the second and third embodiments of the present invention.

### Fifth Embodiment

FIG. 6 is a cross section view illustrating a hybrid solar cell according to the fifth embodiment of the present invention. Except that a first transparent conductive layer 350 is formed instead of a first interfacial layer 300, the hybrid solar cell according to the fifth embodiment of the present invention is identical in structure to the hybrid solar cell shown in FIG. 2 according to the first embodiment of the present invention.

As shown in FIG. 6, the hybrid solar cell according to the fifth embodiment of the present invention is provided with the first transparent conductive layer 350 between a first semiconductor layer 200 and a first electrode 400.

Instead of forming the first interfacial layer 300 between the first semiconductor layer 200 and the first electrode 400, the first transparent conductive layer 350 is formed between the first semiconductor layer 200 and the first electrode 400 in the hybrid solar cell according to the fifth embodiment of the present invention. Also, the hybrid solar cell according to the fifth embodiment of the present invention is provided with a second interfacial layer 600 between a second semiconductor layer 500 and a second electrode 700. Thus, the hybrid solar cell according to the fifth embodiment of the present invention enables to mitigate the following problems (a) and (b): (a) a metal material permeates into the semiconductor layer; and (b) carriers generated in a PN junction structure do not smoothly drift to the electrode.

In this case, a thickness of the first transparent conductive layer 350 is about 110 nm to 600 nm. If the thickness of the first transparent conductive layer 350 is less than 110 nm, the first transparent conductive layer 350 cannot sufficiently serve as the barrier, and also cannot make the smooth collection and drift of the carriers. Meanwhile, if the thickness of the first transparent conductive layer 350 is more than 600 nm, the short-circuit current density may be lowered.

### Sixth Embodiment

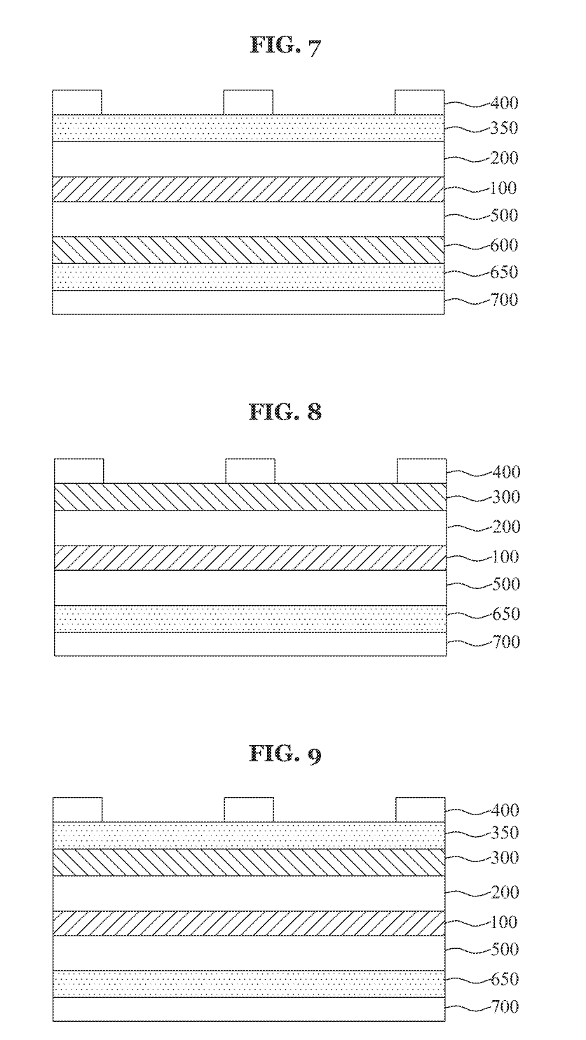

FIG. 7 is a cross section view illustrating a hybrid solar cell according to the sixth embodiment of the present invention. Except that a first transparent conductive layer 350 is formed instead of a first interfacial layer 300, and a second transparent conductive layer 650 is additionally formed between a second interfacial layer 600 and a second electrode 700; the hybrid solar cell according to the sixth embodiment of the present invention is identical in structure to the hybrid solar cell shown in FIG. 2 according to the first embodiment of the present invention.

As shown in FIG. 7, the hybrid solar cell according to the sixth embodiment of the present invention is provided with the first and second transparent conductive layers 350 and 650, wherein the first transparent conductive layer 350 is formed between a first semiconductor layer 200 and a first electrode 400, and the second transparent conductive layer 650 is formed between a second interfacial layer 600 and a second electrode 700.

In this case, a thickness of the first transparent conductive layer 350 is about 110 nm to 600 nm; a thickness of the second interfacial layer 600 is about 5 nm to 50 nm; and a thickness of the second transparent conductive layer 650 is about 60 nm to 180 nm.

### Seventh Embodiment

FIG. 8 is a cross section view illustrating a hybrid solar cell according to the seventh embodiment of the present invention. Except that a second transparent conductive layer 650 is formed instead of a second interfacial layer 600, the hybrid solar cell according to the seventh embodiment of the present invention is identical in structure to the hybrid solar cell shown in FIG. 2 according to the first embodiment of the present invention.

As shown in FIG. 8, the hybrid solar cell according to the seventh embodiment of the present invention is provided with the second transparent conductive layer 650 between a second semiconductor layer 500 and a second electrode 700.

Instead of forming the second interfacial layer 600 between the second semiconductor layer 500 and the second electrode 700, the second transparent conductive layer 650 is formed between the second semiconductor layer 500 and the second electrode 700 in the hybrid solar cell according to the seventh embodiment of the present invention. Also, the hybrid solar cell according to the seventh embodiment of the present invention is provided with a first interfacial layer 300 formed between a first semiconductor layer 200 and a first electrode 400. Thus, the hybrid solar cell according to the seventh embodiment of the present invention enables to mitigate the following problems (a) and (b): (a) a metal material permeates into the semiconductor layer; and (b) carriers generated in a PN junction structure do not smoothly drift to the electrode.

In this case, a thickness of the second transparent conductive layer 650 is about 110 nm to 600 nm. If the thickness of the second transparent conductive layer 650 is less than 110 nm, the second transparent conductive layer 650 cannot sufficiently serve as the barrier, and also cannot make the smooth collection and drift of the carriers. Meanwhile, if the thickness of the second transparent conductive layer 650 is more than 600 nm, the short-circuit current density may be lowered.

### Eighth Embodiment

FIG. 9 is a cross section view illustrating a hybrid solar cell according to the eighth embodiment of the present invention. Except that a second transparent conductive layer 650 is formed instead of a second interfacial layer 600, and a first transparent conductive layer 350 is additionally formed between a first interfacial layer 300 and a first electrode 400, the hybrid solar cell according to the eighth embodiment of the present invention is identical in structure to the hybrid solar cell shown in FIG. 2 according to the first embodiment of the present invention.

As shown in FIG. 9, the hybrid solar cell according to the eighth embodiment of the present invention is provided with the first and second transparent conductive layers 350 and 650, wherein the first transparent conductive layer 350 is formed between the first interfacial layer 300 and the first electrode 400, and the second transparent conductive layer 650 is formed between a second semiconductor layer 500 and a second electrode 700.

In this case, a thickness of the second transparent conductive layer 650 is about 110 nm to 600 nm; a thickness of the first interfacial layer 300 is about 5 nm to 50 nm; and a thickness of the first transparent conductive layer 350 is about 60 nm to 180 nm.

### Ninth Embodiment

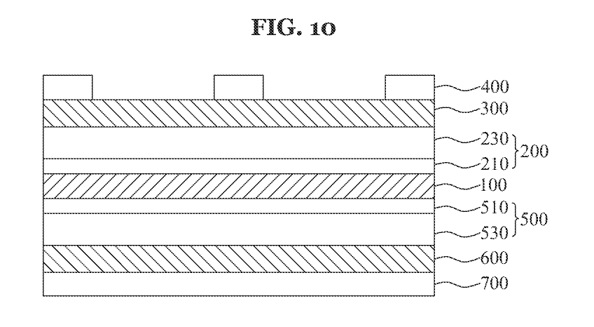

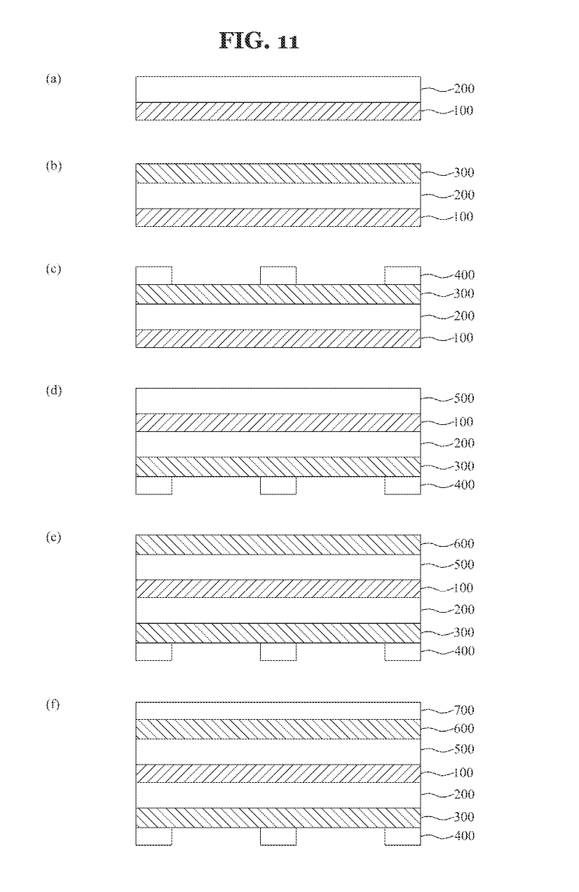

FIG. 10 is a cross section view illustrating a hybrid solar cell according to the ninth embodiment of the present invention. Except that first and second semiconductor layers 200 and 500 are changed in structure, the hybrid solar cell according to the ninth embodiment of the present invention is identical in structure to the hybrid solar cell shown in FIG. 2 according to the first embodiment of the present invention.

As shown in FIG. 10, the hybrid solar cell according to the ninth embodiment of the present invention is provided with the first semiconductor layer 200; wherein the first semiconductor layer 200 includes a lightly doped P-type semiconductor layer 210 on an upper surface of a semiconductor wafer 100, and a highly doped P-type semiconductor layer 230 on the lightly doped P-type semiconductor layer 210. Herein, the lightly or highly doped layers are relative concepts. This indicates that a doping concentration of group III element of the periodic table in the lightly doped P-type semiconductor layer 210 is relatively lower than a doping concentration of group III element of the periodic table in the highly doped P-type semiconductor layer 230.

The lightly doped P-type semiconductor layer 210 enhances the interfacial property between the semiconductor wafer 100 and the highly doped P-type semiconductor layer 230. This will be explained in detail. A doping gas may cause a defect in a surface of the semiconductor wafer 100. As shown in the hybrid solar cell according to the ninth embodiment of the present invention, when the lightly doped P-type semiconductor layer 210 is firstly formed on the surface of the semiconductor wafer 100, and then the highly doped P-type semiconductor layer 230 is formed on the lightly doped P-type semiconductor layer 210, it is possible to prevent the defect from occurring in the surface of the semiconductor wafer 100, thereby improving the cell efficiency by the increase of open-circuit voltage. Preferably, the doping concentration in the lightly doped P-type semiconductor layer 210 is regulated to have such level as to prevent the occurrence of defect in the surface of the semiconductor wafer 100.

When an I(intrinsic)-type semiconductor layer is formed between the semiconductor wafer 100 and the highly doped P-type semiconductor layer 230, it is possible to prevent the defect from occurring in the surface of the semiconductor wafer 100, the defect caused by the doping gas. However, since a process for forming the I-type semiconductor layer has to be additionally carried out, it requires an additional deposition apparatus, thereby causing complexity in process. According to the ninth embodiment of the present invention, since both the lightly doped P-type semiconductor layer 210 and the highly doped P-type semiconductor layer 230 are sequentially formed in one chamber, it is possible to prevent the occurrence of defect in the surface of the semiconductor wafer 100 without an additional apparatus and process.

Also, the second semiconductor layer 500 includes a lightly doped N-type semiconductor layer 510 on a lower surface of the semiconductor wafer 100, and a highly doped N-type semiconductor layer 530 on the lightly doped N-type semiconductor layer 510.

The lightly doped N-type semiconductor layer 510 is similar in function to the lightly doped P-type semiconductor layer 210. That is, the lightly doped N-type semiconductor layer 510 prevents occurrence of the defect in the surface of the semiconductor wafer 100, the defect caused by the doping gas. Thus, the doping concentration in the lightly doped N-type semiconductor layer 510 is regulated to have such level as to prevent the occurrence of defect in the surface of the semiconductor wafer 100, preferably. As mentioned above, since both the lightly doped N-type semiconductor layer 510 and the highly doped N-type semiconductor layer 530 are sequentially formed in one chamber, it is possible to prevent the occurrence of defect in the surface of the semiconductor wafer 100 without an additional apparatus and process.

In the meantime, the first semiconductor layer 200 may comprise a lightly doped N-type semiconductor layer 210 and a highly doped N-type semiconductor layer 230; and the second semiconductor layer 500 may comprise a lightly doped P-type semiconductor layer 510 and a highly doped P-type semiconductor layer 530.

The various embodiments from the second to eighth embodiments of the present invention may be applied to the ninth embodiment of the present invention shown in FIG. 10. That is, the hybrid solar cell shown in FIG. 10 according to the ninth embodiment of the present invention may be provided with a first transparent conductive layer 350 additionally formed between a first interfacial layer 300 and a first electrode 400; may be provided with a second transparent conductive layer 650 additionally formed between a second interfacial layer 600 and a second electrode 700; may be provided with a first transparent conductive layer 350 instead of a first interfacial layer 300; or may be provided with a second transparent conductive layer 650 instead of a second interfacial layer 600.

### Method for Manufacturing Hybrid Solar Cell

Hereinafter, a method for manufacturing the aforementioned hybrid solar cell according to the present invention will be described as follows, wherein redundancy related with the same structures such as the thicknesses of the first interfacial layer 300, the first transparent conductive layer 350, the second interfacial layer 600, and the second transparent conductive layer 650 will be eliminated when explaining the respective embodiments of the present invention.

FIG. 11(A to F) is a series of cross section views illustrating the hybrid solar cell according to one embodiment of the present invention, which illustrates the method for manufacturing the hybrid solar cell shown in FIG. 2 according to the first embodiment of the present invention.

First, as shown in FIG. 11(A), the first semiconductor layer 200 is formed on the semiconductor wafer 100.

The semiconductor wafer 100 may be formed of the N-type silicon wafer.

A process for forming the first semiconductor layer 200 may comprise forming the P-type semiconductor layer, for example, the P-type amorphous silicon layer on the semiconductor wafer 100 by PECVD (Plasma Enhanced Chemical Vapor Deposition).

As shown in FIG. 11(B), the first interfacial layer 300 is formed on the first semiconductor layer 200.

A process for forming the first interfacial layer 300 may comprise depositing the transparent conductive material such as ZnO:B or ZnO:Al by CVD (Chemical Vapor Deposition) such as MOCVD (Metal Organic Chemical Vapor Deposition).

As shown in FIG. 11(C), the first electrode 400 is formed on the first interfacial layer 300.

At this time, the plurality of first electrodes 400 are patterned at fixed intervals so that solar ray can be transmitted to the inside of the solar cell through the interval provided between each of the first electrodes 400.

A process for forming the first electrode 400 may comprise depositing and patterning the metal material such as Ag, Al, Ag+Al, Ag+Mg, Ag+Mn, Ag+Sb, Ag+Zn, Ag+Mo, Ag+Ni, Ag+Cu, or Ag+Al+Zn by sputtering; or may comprise directly patterning a paste of the aforementioned metal material by a screen-printing method, inkjet-printing method, gravure-printing method, or micro-contact printing method. This printing method enables to pattern the plurality of first electrodes 400 at fixed intervals by one process, thereby resulting in the simplified process.

As shown in FIG. 11(D), after inverting the semiconductor wafer 100, the second semiconductor layer 500 is formed on the semiconductor wafer 100.

A process for forming the second semiconductor layer 500 may comprise forming the N-type semiconductor layer, for example, the N-type amorphous silicon layer on the semiconductor wafer 100 by PECVD (Plasma Enhanced Chemical Vapor Deposition).

As shown in FIG. 11(E), the second interfacial layer 600 is formed on the second semiconductor layer 500.

A process for forming the second interfacial layer 600 may comprise depositing the transparent conductive material such as ZnO:B or ZnO:Al by CVD (Chemical Vapor Deposition) such as MOCVD (Metal Organic Chemical Vapor Deposition).

As shown in FIG. 11(F), the second electrode 700 is formed on the second interfacial layer 600, thereby completing the hybrid solar cell according to one embodiment of the present invention.

A process for forming the second electrode 700 may comprise depositing and patterning the metal material such as Ag, Al, Ag+Al, Ag+Mg, Ag+Mn, Ag+Sb, Ag+Zn, Ag+Mo, Ag+Ni, Ag+Cu, or Ag+Al+Zn; or may comprise directly patterning a paste of the aforementioned metal material by the aforementioned printing method.

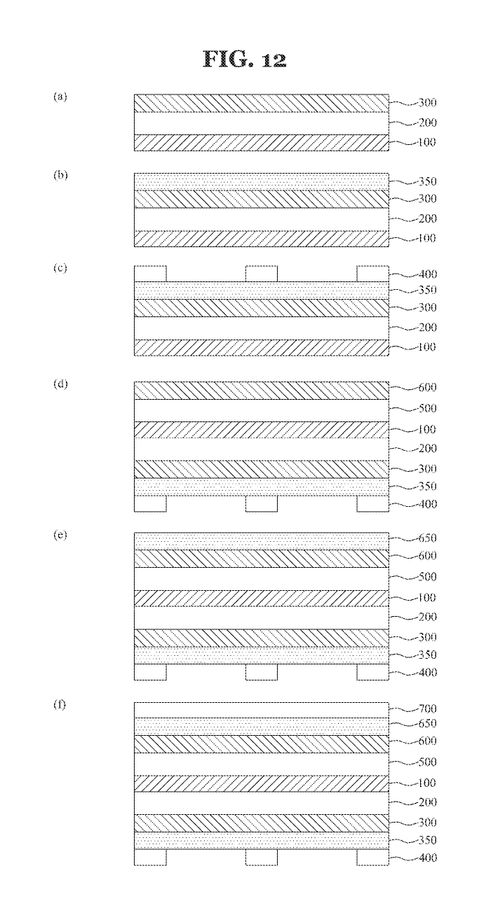

FIG. 12(A to F) is a series of cross section views illustrating a method for manufacturing the hybrid solar cell according to another embodiment of the present invention, which illustrates the method for manufacturing the hybrid solar cell shown in FIG. 5 according to the fourth embodiment of the present invention. A detailed explanation for the same process as the aforementioned process will be omitted.

First, as shown in FIG. 12(A), the first semiconductor layer 200 is formed on the semiconductor wafer 100, and the first interfacial layer 300 is formed on the first semiconductor layer 200.

As shown in FIG. 12(B), the first transparent conductive layer 350 is formed on the first interfacial layer 300.

A process for forming the first transparent conductive layer 350 may comprise depositing the transparent conductive material such as SnO₂, SnO₂:F, or ITO (Indium Tin Oxide) by sputtering or MOCVD (Metal Organic Chemical Vapor Deposition).

As shown in FIG. 12(C), the first electrode 400 is formed on the first transparent conductive layer 350.

As shown in FIG. 12(D), after inverting the semiconductor wafer 100, the second semiconductor layer 500 is formed on the semiconductor wafer 100, and then the second interfacial layer 600 is formed on the second semiconductor layer 500.

As shown in FIG. 12(E), the second transparent conductive layer 650 is formed on the second interfacial layer 600.

A process for forming the second transparent conductive layer 650 may comprise depositing the transparent conductive material such as SnO₂, SnO₂:F, or ITO (Indium Tin Oxide) by sputtering or MOCVD (Metal Organic Chemical Vapor Deposition).

As shown in FIG. 12(F), the second electrode 700 is formed on the second transparent conductive layer 650, thereby completing the hybrid solar cell according to another embodiment of the present invention.

If appropriately changing the process of FIG. 12(A to F), it is possible to obtain the hybrid solar cell shown in FIG. 3 according to the second embodiment of the present invention, the hybrid solar cell shown in FIG. 4 according to the third embodiment of the present invention, the hybrid solar cell shown in FIG. 6 according to the fifth embodiment of the present invention, the hybrid solar cell shown in FIG. 7 according to the sixth embodiment of the present invention, the hybrid solar cell shown in FIG. 8 according to the seventh embodiment of the present invention, or the hybrid solar cell shown in FIG. 9 according to the eighth embodiment of the present invention.

That is, if omitting the step for forming the second transparent conductive layer 650 from the process of FIG. 12(A to F), it is possible to obtain the hybrid solar cell shown in FIG. 3 according to the second embodiment of the present invention.

If omitting the step for forming the first transparent conductive layer 350 from the process of FIG. 12(A to F), it is possible to obtain the hybrid solar cell shown in FIG. 4 according to the third embodiment of the present invention.

If omitting the steps for forming the first interfacial layer 300 and the second transparent conductive layer 650 from the process of FIG. 12(A to F), it is possible to obtain the hybrid solar cell shown in FIG. 6 according to the fifth embodiment of the present invention.

If omitting the step for forming the first interfacial layer 300 from the process of FIG. 12(A to F), it is possible to obtain the hybrid solar cell shown in FIG. 7 according to the sixth embodiment of the present invention.

If omitting the step for forming the second interfacial layer 600 and the first transparent conductive layer 350 from the process of FIG. 12(A to F), it is possible to obtain the hybrid solar cell shown in FIG. 8 according to the seventh embodiment of the present invention.

If omitting the step for forming the second interfacial layer 600 from the process of FIG. 12(A to F), it is possible to obtain the hybrid solar cell shown in FIG. 9 according to the eighth embodiment of the present invention.

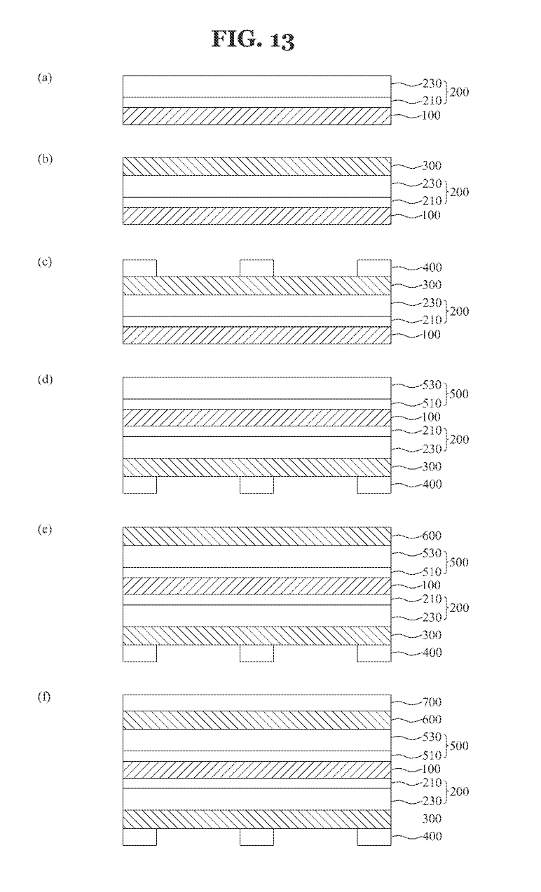

FIG. 13(A to F) is a series of cross section views illustrating a method for manufacturing the hybrid solar cell according to another embodiment of the present invention, which illustrates the method for manufacturing the hybrid solar cell shown in FIG. 10 according to the ninth embodiment of the present invention. A detailed explanation for the same process as the aforementioned process will be omitted.

First, as shown in FIG. 13(A), the first semiconductor layer 200 is formed on the semiconductor wafer 100.

A process for forming the first semiconductor layer 200 may comprise forming the lightly doped P-type semiconductor layer 210 on the semiconductor wafer 100, and forming the highly doped P-type semiconductor layer 230 on the lightly doped P-type semiconductor layer 210.

Both the lightly doped P-type semiconductor layer 210 and the highly doped P-type semiconductor layer 230 may be sequentially formed in one chamber. That is, the lightly doped P-type semiconductor layer 210 and the highly doped P-type semiconductor layer 230 may be formed sequentially by regulating a supplying amount of dopant gas of group III element of the periodic table, for example, as boron (B) in one PECVD (Plasma Enhanced Chemical Vapor Deposition) chamber.

For manufacturing an initial solar cell in mass production, the P-type dopant atmosphere is created inside the chamber by supplying a predetermined amount of B₂H₆ gas to the inside of the chamber, and then SiH₄ and H₂ gases are supplied to the inside of the chamber, to thereby form the lightly doped P-type semiconductor layer 210, and more particularly, the lightly doped P-type amorphous silicon layer. Thereafter, when supplying SiH₄ and H₂ gases, B₂H₆ gas serving as the dopant gas is additionally supplied to the inside of the chamber, thereby forming the highly doped P-type semiconductor layer 230, and more particularly, the highly doped P-type amorphous silicon layer.

After completing the process for forming the highly doped P-type semiconductor layer 230, some of B₂H₆ gas may remain in the chamber. From the process for manufacturing the following solar cells after the initial solar cell, the inside of the chamber is already prepared with the P-type dopant atmosphere. Thus, only SiH₄ and H₂ gases are supplied to the inside of the chamber without supplying B₂H₆ gas to the inside of the chamber, to thereby form the lightly doped P-type semiconductor layer 210. Thereafter, when supplying SiH₄ and H₂ gases, B₂H₆ gas serving as the dopant gas is additionally supplied to the inside of the chamber, thereby forming the highly doped P-type semiconductor layer 230.

As explained above, since both the lightly doped P-type semiconductor layer 210 and the highly doped P-type semiconductor layer 230 can be sequentially formed in one chamber by regulating the supplying amount of reaction gases in one chamber, there is no requirement for the additional apparatus and process, thereby resulting in improvement of the yield.

As shown in FIG. 13(B), the first interfacial layer 300 is formed on the first semiconductor layer 200.

As shown in FIG. 13(C), the first electrode 400 is formed on the first interfacial layer 300.

As shown in FIG. 13(D), after inverting the semiconductor wafer 100, the second semiconductor layer 500 is formed on the semiconductor wafer 100.

A process for forming the second semiconductor layer 500 may comprise forming the lightly doped N-type semiconductor layer 510 on the semiconductor wafer 100, and forming the highly doped N-type semiconductor layer 530 on the lightly doped N-type semiconductor layer 510.

With similarity to the lightly doped P-type semiconductor layer 210 and the highly doped P-type semiconductor layer 230, both the lightly doped N-type semiconductor layer 510 and the highly doped N-type semiconductor layer 530 can be sequentially formed in one chamber. That is, the lightly doped N-type semiconductor layer 510 and the highly doped N-type semiconductor layer 530 may be formed sequentially by regulating a supplying amount of dopant gas of group V element of the periodic table, for example, phosphorous (P) in one PECVD (Plasma Enhanced Chemical Vapor Deposition) chamber.

In more detail, after the N-type dopant atmosphere is created inside the chamber by supplying a predetermined amount of PH₃ gas to the inside of the chamber, SiH₄ and H₂ gases are supplied to the inside of the chamber, thereby forming the lightly doped N-type semiconductor layer 510. Thereafter, when supplying SiH₄ and H₂ gases, PH₃ gas serving as the dopant gas is additionally supplied to the inside of the chamber, thereby forming the highly doped N-type semiconductor layer 530.

With similarity to the aforementioned process for forming the P-type semiconductor layer 200, some of PH₃ gas may remain in the chamber after completing the process for forming the highly doped N-type semiconductor layer 530. From the process for manufacturing the following solar cells after the initial solar cell, the inside of the chamber is already prepared with the N-type dopant atmosphere. Thus, only SiH₄ and H₂ gases are supplied to the inside of the chamber without supplying the additional dopant gas of PH₃ gas to the inside of the chamber, to thereby form the lightly doped N-type semiconductor layer 510. Thereafter, when supplying SiH₄ and H₂ gases, PH₃ gas serving as the dopant gas is additionally supplied to the inside of the chamber, to thereby form the highly doped N-type semiconductor layer 530.

As shown in FIG. 13(E), the second interfacial layer 600 is formed on the second semiconductor layer 500.

As shown in FIG. 13(F), the second electrode 700 is formed on the second interfacial layer 600, thereby completing the hybrid solar cell according to another embodiment of the present invention.

As explained above, the process of FIG. 13(A to F) may be provided with the additional step for forming the first transparent conductive layer 350 between the steps of forming the first interfacial layer 300 and the first electrode 400; the additional step for forming the second transparent conductive layer 650 between the steps for forming the second interfacial layer 600 and the second electrode 700; the additional step for forming the first transparent conductive layer 350 instead of omitting the step for forming the first interfacial layer 300; or the additional step for forming the second transparent conductive layer 650 instead of omitting the step for forming the second interfacial layer 600.

According to the aforementioned methods, the first semiconductor layer 200, the first interfacial layer 300, the first transparent conductive layer 350, and the first electrode 400 are sequentially formed on the upper surface of the semiconductor wafer 100; and then the second semiconductor layer 500, the second interfacial layer 600, the second transparent conductive layer 650, and the second electrode 700 are sequentially formed on the lower surface of the semiconductor wafer 100. However, the method for manufacturing the hybrid solar cell according to the present invention may have various modifications.

For example, the modified method for manufacturing the hybrid solar cell according to the present invention may comprise the sequential steps for forming the first semiconductor layer 200 on the upper surface of the semiconductor wafer 100; forming the second semiconductor layer 500 on the lower surface of the semiconductor wafer 100; forming the first interfacial layer 300 on the first semiconductor layer 200; forming the second interfacial layer 600 on the second semiconductor layer 500; forming the first transparent conductive layer 350 on the first interfacial layer 300; forming the second transparent conductive layer 650 on the second interfacial layer 600; forming the first electrode 400 on the first transparent conductive layer 350; and forming the second electrode 700 on the second transparent conductive layer 650.

According to the aforementioned methods, the semiconductor wafer 100 is formed of the N-type semiconductor wafer; the first semiconductor layer 200 is formed of the P-type semiconductor layer; and the second semiconductor layer 500 is formed of the N-type semiconductor layer, but not necessarily. The aforementioned methods may have various modifications within the scope of maintaining the PN junction structure and the hybrid type comprising the semiconductor wafer and the thin film of semiconductor layer. For example, the semiconductor wafer 100 may be formed of the P-type semiconductor wafer; the first semiconductor layer 200 may be formed of the N-type semiconductor layer; and the second semiconductor layer 500 may be formed of the P-type semiconductor layer.

Accordingly, the hybrid solar cell according to the present invention and the method for manufacturing the same has the following advantages.

The hybrid solar cell according to the present invention is provided with the interfacial layer between the first semiconductor layer and the first electrode and/or between the second semiconductor layer and the second electrode, so that it is possible to prevent the material of the electrode from permeating into the semiconductor layer, and to collect the carriers in the semiconductor wafer 100 and to smoothly drift the collected carriers to the electrode, thereby improving the cell efficiency.

Also, the interfacial layer is formed of the transparent conductive material containing ZnO, which is suitable for the chemical vapor deposition method such as MOCVD (Metal Organic Chemical Vapor Deposition). Thus, even though the semiconductor layer is provided with the uneven surface, the interfacial layer may be provided with the even surface, thereby preventing the defect such as the void in the interfacial layer, enhancing the barrier function, and maximizing the collection and drift of the carriers.

Also, the lightly doped semiconductor layer is firstly formed on the semiconductor wafer 100, and then the highly doped semiconductor layer is secondly formed on the lightly doped semiconductor layer, thereby preventing the defect in the surface of the semiconductor wafer 100. As a result, the open-circuit voltage is increased so that the cell efficiency is improved.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A hybrid solar cell comprising:
a semiconductor wafer having a predetermined polarity;
a first semiconductor layer on one surface of the semiconductor wafer;
a second semiconductor layer on another surface of the semiconductor wafer, wherein the second semiconductor layer has a polarity different from a polarity of the first semiconductor layer;
a first electrode on the first semiconductor layer;
a second electrode on the second semiconductor layer; and
at least one interfacial layer, comprising (i) a first interfacial layer containing ZnO between the first semiconductor layer and the first electrode, or (ii) a second interfacial layer containing ZnO between the second semiconductor layer and the second electrode.

2. The hybrid solar cell of claim 1, comprising the first interfacial layer between the first semiconductor layer and the first electrode, and further comprising a first transparent conductive layer between the first interfacial layer and the first electrode.

3. The hybrid solar cell of claim 1, comprising the second interfacial layer between the second semiconductor layer and the second electrode, and further comprising a second transparent conductive layer between the second interfacial layer and the second electrode.

4. The hybrid solar cell of claim 1, comprising the first interfacial layer between the first semiconductor layer and the first electrode, and the second interfacial layer between the second semiconductor layer and the second electrode; and
further comprising a first transparent conductive layer between the first interfacial layer and the first electrode, and a second transparent conductive layer between the second interfacial layer and the second electrode.

5. The hybrid solar cell of claim 1, comprising the second interfacial layer between the second semiconductor layer and the second electrode, and further comprising a first transparent conductive layer between the first semiconductor layer and the first electrode.

6. The hybrid solar cell of claim 5, further comprising a second transparent conductive layer between the second interfacial layer and the second electrode.

7. The hybrid solar cell of claim 1, comprising the first interfacial layer between the first semiconductor layer and the first electrode, and further comprising a second transparent conductive layer between the second semiconductor layer and the second electrode.

8. The hybrid solar cell of claim 7, further comprising a first transparent conductive layer between the first interfacial layer and the first electrode.

9. The hybrid solar cell of claim 1, wherein the first semiconductor layer comprises a lightly doped first semiconductor layer on the one surface of the semiconductor wafer, and a highly doped first semiconductor layer on the lightly doped first semiconductor layer.

10. The hybrid solar cell of claim 1, wherein the second semiconductor layer comprises a lightly doped second semiconductor layer on the other surface of the semiconductor wafer, and a highly doped second semiconductor layer on the lightly doped second semiconductor layer.

11. The hybrid solar cell of claim 1, wherein the at least one interfacial layer comprises ZnO:B or ZnO:Al.

12. The hybrid solar cell of claim 1, wherein the at least one interfacial layer has a thickness of 110 nm to 600 nm.

13. The hybrid solar cell of claim 2, wherein the first interfacial layer has a thickness of 5 nm to 50 nm, and the first transparent conductive layer has a thickness of 60 nm to 180 nm.

14. The hybrid solar cell of claim 3, wherein the second interfacial layer has a thickness of 5 nm to 50 nm, and the second transparent conductive layer has a thickness of 60 nm to 180 nm.

15. The hybrid solar cell of claim 1, wherein the semiconductor wafer is identical in polarity to any one of the first and second semiconductor layers.

16. A method for manufacturing a hybrid solar cell comprising:
forming a first semiconductor layer on one surface of a semiconductor wafer having a predetermined polarity;
forming a first interfacial layer containing ZnO on the first semiconductor layer by CVD;
forming a first electrode on the first interfacial layer;
forming a second semiconductor layer on another surface of the semiconductor wafer, wherein the second semiconductor layer has a polarity different from a polarity of the first semiconductor layer;
forming a second interfacial layer containing ZnO on the second semiconductor layer by CVD; and
forming a second electrode on the second interfacial layer.

17. The method of claim 16, further comprising forming a first transparent conductive layer between forming the first interfacial layer and forming the first electrode.

18. The method of claim 16, further comprising forming a second transparent conductive layer between forming the second interfacial layer and forming the second electrode.

19. The method of claim 16, further comprising forming a first transparent conductive layer between forming the first interfacial layer and forming the first electrode, and forming a second transparent conductive layer between forming the second interfacial layer and forming the second electrode.

20. A method for manufacturing a hybrid solar cell comprising:
forming a first semiconductor layer on one surface of a semiconductor wafer having a predetermined polarity;
forming a first transparent conductive layer on the first semiconductor layer;
forming a first electrode on the first transparent conductive layer;
forming a second semiconductor layer on another surface of the semiconductor wafer, wherein the second semiconductor layer has a polarity different from a polarity of the first semiconductor layer;
forming a second interfacial layer containing ZnO on the second semiconductor layer by CVD; and
forming a second electrode on the second interfacial layer.

21. The method of claim 20, further comprising forming a second transparent conductive layer between forming the second interfacial layer and forming the second electrode.

22. A method for manufacturing a hybrid solar cell comprising:
forming a first semiconductor layer on one surface of a semiconductor wafer having a predetermined polarity;
forming a first interfacial layer containing ZnO on the first semiconductor layer by CVD;
forming a first electrode on the first interfacial layer;
forming a second semiconductor layer on another surface of the semiconductor wafer, wherein the second semiconductor layer has a polarity different from a polarity of the first semiconductor layer;
forming a second transparent conductive layer on the second semiconductor layer; and
forming a second electrode on the second transparent conductive layer.

23. The method of claim 22, further comprising forming a first transparent conductive layer between forming the first interfacial layer and forming the first electrode.

24. The method of claim 22, wherein forming the first semiconductor layer comprises:
forming a lightly doped first semiconductor layer on the one surface of the semiconductor wafer; and
forming a highly doped first semiconductor layer on the lightly doped first semiconductor layer.

25. The method of claim 24, wherein forming the lightly doped first semiconductor layer and forming the highly doped first semiconductor layer are sequentially carried out in one chamber.

26. The method of claim 25, wherein:
forming the lightly doped first semiconductor layer is carried out without additionally supplying a predetermined dopant to the chamber prepared in a predetermined dopant atmosphere; and
forming the highly doped first semiconductor layer is carried out by supplying the predetermined dopant to the chamber.

27. The method of claim 22, wherein forming the second semiconductor layer comprises:
forming a lightly doped second semiconductor layer on the other surface of the semiconductor wafer; and
forming a highly doped second semiconductor layer on the lightly doped second semiconductor layer.

28. The method of claim 16, wherein forming the first semiconductor layer comprises:
forming a lightly doped first semiconductor layer on the one surface of the semiconductor wafer; and
forming a highly doped first semiconductor layer on the lightly doped first semiconductor layer.

29. The method of claim 28, wherein forming the lightly doped first semiconductor layer and forming the highly doped first semiconductor layer are sequentially carried out in one chamber.

30. The method of claim 29, wherein:
forming the lightly doped first semiconductor layer is carried out without additionally supplying a predetermined dopant to the chamber prepared in a predetermined dopant atmosphere; and
forming the highly doped first semiconductor layer is carried out by supplying the predetermined dopant to the chamber.

31. The method of claim 16, wherein forming the second semiconductor layer comprises:
forming a lightly doped second semiconductor layer on the other surface of the semiconductor wafer; and
forming a highly doped second semiconductor layer on the lightly doped second semiconductor layer.
